(19) United States
(12) Patent Application Publication
(10) Pub. No.: US 2024/0423062 A1
(43) Pub. Date: Dec. 19, 2024

(54) FLEXIBLE DISPLAY DEVICE

(71) Applicant: SAMSUNG DISPLAY CO., LTD., Yongin-si (KR)

(72) Inventors: Gyu Tae KIM, Yongin-si (KR); Byeong In PARK, Yongin-si (KR); Chul Ho JUNG, Yongin-si (KR)

(21) Appl. No.: 18/408,717

(22) Filed: Jan. 10, 2024

(30) Foreign Application Priority Data
Jun. 15, 2023 (KR) 10-2023-0077025

(51) Int. Cl. H10K 59/80; H01L 25/16

(52) U.S. Cl. CPC H10K 59/87; H01L 25/167

(57) ABSTRACT

A display device includes: unfoldable areas and foldable areas; a window; a display panel disposed under the window; a first support member disposed under the display panel in the unfoldable areas and the foldable area to support the display panel, and including a discontinuous portion having openings or grooves in the foldable area; a second support member disposed under the first support member and including sub-plates respectively overlapping the unfoldable areas; and an adhesive member disposed between the first support member and the second support member, wherein each of the sub-plates of the second support member includes a first portion, a second portion, and a third portion, wherein the first portion extends parallel to the first support member, wherein the second portion extends from the first portion and is bent in the foldable area, and wherein the third portion extends parallel to the first support member from the second portion.

### CROSS-REFERENCE TO RELATED APPLICATION

The application claims priority under 35 U.S.C. § 119 (a) to Korean Patent Application No. 10-2023-0077025, filed on Jun. 15, 2023, the disclosure of which is incorporated by reference herein in its entirety.

### TECHNICAL FIELD

The present invention relates to a display device, and more particularly, to a flexible display device.

### DISCUSSION OF THE RELATED ART

Multimedia electronic devices such as televisions, mobile phones, tablet computers, navigation devices, and game machines may include a display device for displaying an image. The display device may be, for example, an organic light emitting display, a liquid crystal display, a plasma display panel (PDP), or the like.

Recently, demand for a flexible display device has been increasing. Unlike a rigid display device, the flexible display device may be bent, folded, or rolled. As such, the flexible display device may be deformed into various shapes. Accordingly, the flexible display device may be easy to carry and can increase user convenience. In addition, since the flexible display device can be implemented in various forms such as a bendable display device, a foldable display device, and a rollable display device, its application fields are expanding. For example, to implement a large area along with ultra-thin, light weight, and miniaturization, research on a foldable display device that is portable in a folded state and displays an image in an unfolded state is being actively conducted and such a device is currently under development.

### SUMMARY

According to an embodiment of the present invention, a display device includes: unfoldable areas and foldable areas disposed between the unfoldable areas; a window; a display panel disposed under the window; a first support member disposed under the display panel in the unfoldable areas and the foldable area to support the display panel, and including a discontinuous portion having openings or grooves in the foldable area; a second support member disposed under the first support member and including sub-plates respectively overlapping the unfoldable areas; and an adhesive member disposed between the first support member and the second support member, wherein each of the sub-plates of the second support member includes a first portion, a second portion, and a third portion, wherein the first portion extends parallel to the first support member, wherein the second portion extends from the first portion and is bent in the foldable area, and wherein the third portion extends parallel to the first support member from the second portion.

In an embodiment of the present invention, the second portion of each of the sub-plates is folded inwardly in a direction toward the first support member to contact the discontinuous portion of the first support member.

In an embodiment of the present invention, the sub-plates are spaced apart from each other in the foldable area.

In an embodiment of the present invention, the second portion of each of the sub-plates is folded by bending end portions of the sub-plates facing each other in the foldable area.

In an embodiment of the present invention, the third portion of each of the sub-plates is disposed between the first portion of a corresponding sub-plate and the first support member.

In an embodiment of the present invention, the adhesive member is disposed on a portion of the first portion that does not overlap the third portion of each of the sub-plates.

In an embodiment of the present invention, the adhesive member is disposed to have the same thickness as the second support member, wherein the adhesive member attaches the first portion to the first support member.

In an embodiment of the present invention, the adhesive member includes at least one of a pressure sensitive adhesive, an optically clear adhesive, or an optically clear resin.

In an embodiment of the present invention, the first support member includes at least one stainless steel, aluminum alloy, copper alloy, plastic (carbon fiber reinforced plastics), or ultra thin glass.

In an embodiment of the present invention, the second support member includes at least one of stainless steel, aluminum alloy, or copper alloy.

In an embodiment of the present invention, each of the sub-plates of the second support member further includes a fourth portion and a fifth portion, wherein the fourth portion extends from the first portion and is bent, and wherein the fifth portion extends parallel to the first support member from the fourth portion, and wherein the first portion is disposed between the second portion and the fourth portion.

In an embodiment of the present invention, the fourth portion of each of the sub-plates is folded inwardly in a direction toward the first support member to contact an edge portion of the first support member.

In an embodiment of the present invention, the fifth portion of each of the sub-plates is disposed between the first portion of a corresponding sub-plate and the first support member.

In an embodiment of the present invention, the adhesive member is disposed on the first portion of each of the sub-plates and is disposed between the third portion and the fifth portion.

According to an embodiment of the present invention, a display device includes: unfoldable areas and foldable areas disposed between the unfoldable areas; a window; a display panel disposed attached to the window; a first support member attached to the display panel in the unfoldable areas and the foldable area, and including a discontinuous portion having openings or grooves in the foldable area; a second support member disposed under the first support member and including sub-plates respectively overlapping the unfoldable areas and the foldable area; and wherein each of the sub-plates of the second support member includes a first portion, a second portion, and a third portion, wherein the first portion overlaps the first support member, wherein the second portion extends from the first portion and is bent in the foldable area, and wherein the third portion is disposed between the first support member and the first portion.

In an embodiment of the present invention, the display device further includes an adhesive member disposed between the first portion and the first support member.

In an embodiment of the present invention, the adhesive member contacts the first portion and the third portion.

In an embodiment of the present invention, each of the sub-plates of the second support member further includes a fourth portion and a fifth portion, wherein the fourth portion is connected to the first portion and is bent, and wherein the fifth portion is connected to the fourth portion, and wherein the first portion is disposed between the second portion and the fourth portion.

In an embodiment of the present invention, the fifth portion is disposed between the first portion and the first support member.

In an embodiment of the present invention, the display device further includes an adhesive member disposed between the fifth portion and the third portion.

### BRIEF DESCRIPTION OF THE DRAWINGS

The above and other features of the present invention will become more apparent by describing in further detail exemplary embodiments thereof with reference to the accompanying drawings, in which:

FIG. 1 is a perspective view illustrating a display device in an unfolded state according to an embodiment of the present invention.

FIG. 2 is a perspective view illustrating the display device of FIG. 1 in a folded state.

FIG. 3 is a perspective view illustrating a display device in an unfolded state according to an embodiment of the present invention.

FIG. 4 is a perspective view illustrating the display device of FIG. 3 in a folded state.

FIG. 5 is a cross-sectional view illustrating a display device according to an embodiment of the present invention.

FIG. 6 is a cross-sectional view taken along line I-I′ in the display device of FIG. 1, according to an embodiment of the present invention.

FIG. 7 is a cross-sectional view of a display panel of FIG. 6, according to an embodiment of the present invention.

FIG. 8 is a perspective view illustrating a first support member and a second support member of FIG. 6, according to an embodiment of the present invention.

FIG. 9 is a cross-sectional view taken along line I-I′ in the display device of FIG. 1, according to an embodiment of the present invention.

FIG. 10 is a perspective view illustrating a first support member and a second support member of FIG. 9, according to an embodiment of the present invention.

### DETAILED DESCRIPTION OF THE EMBODIMENTS

Hereinafter, various embodiments of the present invention will be described in detail with reference to the accompanying drawings. The present invention may be embodied in various different forms and is not limited to the embodiments described herein.

It will be understood that when an element is referred to as being “connected” or “coupled” to another element, the element may be directly connected or coupled to the other element or intervening elements interposed therebetween. Here, “and/or” includes any and all combinations of one or more of corresponding configurations.

Here, terms such as first and second may be used to describe various components, but these components are not limited to these terms. These terms are used to distinguish one component from another component. Therefore, a first component may refer to a second component without departing from the spirit and scope of the present invention.

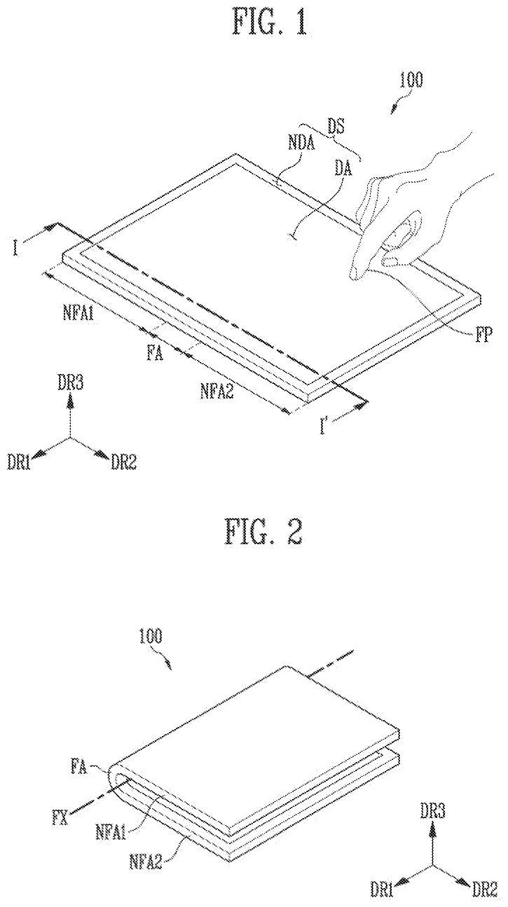

FIG. 1 is a perspective view illustrating a display device in an unfolded state according to an embodiment of the present invention. A display device 100 may be a foldable display device. The display device 100 according to an embodiment of the present invention may be used for large-sized electronic devices such as televisions and monitors, as well as small and medium-sized electronic devices such as mobile phones, tablets, car navigation systems, game consoles, and smart watches.

Referring to FIG. 1, an upper surface of the display device 100 may be defined as a display surface DS. In an unfolded state, in other words, in a flat state of the display device 100, the display surface DS may have a plane defined by a first direction DR1 and a second direction DR2. A normal direction of the display surface DS may be a direction parallel to a third direction DR3. For example, the third direction DR3 may be perpendicular or substantially perpendicular to the first and second directions DR1 and DR2. The third direction DR3 may indicate a thickness direction of the display device 100.

The display surface DS may include a display area DA and a non-display area NDA around and/or adjacent to the display area DA. The display area DA may be an area where an image is displayed, and the non-display area NDA may be an area where an image is not displayed.

In some embodiments of the present invention, the display area DA may have a rectangular shape. The non-display area NDA may partially surround at least a portion of the display area DA. However, embodiments of the present invention are not limited thereto, and the shapes of the display area DA and the non-display area NDA may be variously modified.

The display device 100 may include a first unfoldable area NFA1, a foldable area FA, and a second unfoldable area NFA2 sequentially defined (or arranged) along the second direction DR2 or a direction opposite to the second direction DR2. Here, while the foldable area FA may be an area that is bent according to an applied external force, the first unfoldable area NFA1 and the second unfoldable area NFA2 may be areas that are not bent according to an applied external force. For example, the foldable area FA may be disposed between the first unfoldable area NFA1 and the second unfoldable area NFA2. In FIGS. 1 and 2, one foldable area FA and two unfoldable areas NFA1 and NFA2 are shown as an example, but embodiments of the present invention are not limited thereto. For example, the display device 100 may include more than two unfoldable areas and foldable areas disposed between the unfoldable areas.

FIG. 2 is a perspective view illustrating the display device of FIG. 1 in a folded state.

Referring to FIG. 2, the display device 100 may be folded based on a folding axis FX. The foldable area FA may be bent based on the folding axis FX. In some embodiments of the present invention, the folding axis FX may be a short axis parallel to a short side of the display device 100. For example, the folding axis FX may extend along the first direction DR1.

The display device 100 may be folded inwardly based on the folding axis FX. In this case, when the display device 100 is folded, a display surface of the first unfoldable area NFA1 and a display surface of the second unfoldable area NFA2 may face each other. For example, the display device 100 may be folded such that the display surface DS is positioned inside the display device 100 when in the folded state. However, embodiments of the present invention are not limited thereto. For example, the display device 100 may be folded outwardly based on the folding axis FX. In this case, when the display device 100 is folded, the display surface of the first unfoldable area NFA1 and the display surface of the second unfoldable area NFA2 may face opposite directions to each other. For example, the display device 100 may be folded such that the display surface DS is exposed to the outside of the display device 100.

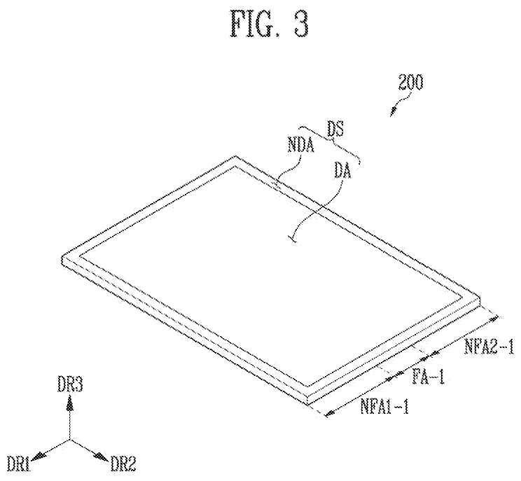

FIG. 3 is a perspective view illustrating a display device in an unfolded state according to an embodiment of the present invention.

Referring to FIG. 3, a display device 200 may include a first unfoldable area NFA1-1, a foldable area FA-1, and a second unfoldable area NFA2-1 sequentially defined (or arranged) along the first direction DR1 or a direction opposite to the first direction DR1. The foldable area FA-1 may be disposed between the first unfoldable area NFA1-1 and the second unfoldable area NFA2-1.

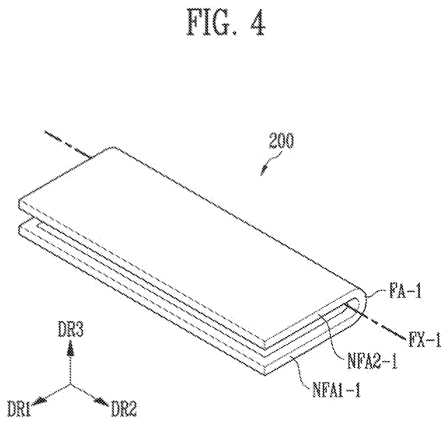

FIG. 4 is a perspective view illustrating the display device of FIG. 3 in a folded state.

Referring to FIG. 4, the display device 200 may be folded based on a folding axis FX-1. The foldable area FA-1 may be bent based on the folding axis FX-1. In some embodiments of the present invention, the folding axis FX-1 may be a long axis extending parallel to a long side of the display device 200. For example, the folding axis FX-1 may extend along the second direction DR2.

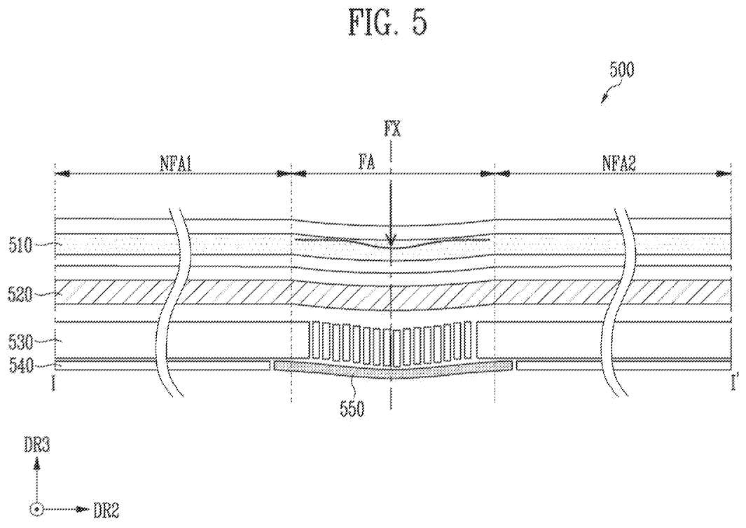

As such, the display device may include a folding axis aligned along one of various directions, such as the folding axis FX of FIG. 3 and the folding axis FX-1 of FIG. 5, and may be folded based on the folding axis. Hereinafter, structures of the display device 100 of FIGS. 1 and 2 that are folded based on a short axis will be described. However, embodiments of the present invention are not limited thereto. For example, structures of the display device 100 to be described below may also be applied to the display device 200 that is folded based on a long axis.

FIG. 5 is a cross-sectional view illustrating a display device according to an embodiment of the present invention.

Referring to FIG. 5, a display device 500 may include a window 510, a display panel 520, and a support member 530.

The window 510 may cover the display panel 520 to protect the display panel 520. The display panel 520 may generate an image. When the display device 500 is a foldable display device, the window 510 may have a relatively thinner thickness and relatively lower rigidity than a window employed in an unfoldable display device.

In addition, the window 510 may include glass. In this case, the window 510 may have a thickness of less than about 100 micrometers or less than about 80 micrometers so as to be foldable. For example, the window 510 may have a thickness of about 30 micrometers. The window 510 may include ultra-thin tempered glass (UTG). As such, the window 510 may have a relatively thinner thickness than a window employed in an unfoldable (or rigid) display device. This may mean that the window 510 has a relatively low rigidity. Therefore, compared to an unfoldable display device, in the display device 500, the support member 530 for supplementing the relatively low rigidity of the window 510 may be disposed under the display panel 520.

The support member 530 may include a relatively highly rigid material such as stainless steel to support components of the display device 500 and may have a relatively thick thickness. However, as an adhesive layer 540 is disposed under the support member 530 corresponding to the unfoldable areas NFA1 and NFA2, a step difference according to a manufacturing process may occur at a lower portion of the support member 530 corresponding to the foldable area FA. Accordingly, a separate support member 550 may be disposed under the support member 530 corresponding to the foldable area FA. For example, the adhesive layer 540 may be disposed under the support member 530, which corresponds to the unfoldable areas NFA1 and NFA2, with a thickness of about 20 micrometers to bond the support member 530 and a digitizer to each other. In this case, the adhesive layer 540 may include an adhesive and/or a pressure-sensitive adhesive. In addition, the support member 550 having a thickness of about 16 micrometers may be disposed under the support member 530 corresponding to the foldable area FA to support the discontinuous portion having openings of the support member 530. In this case, the support member 550 may be a thermoplastic polyurethane elastomer (TPU).

Accordingly, when the display device 100 is repeatedly folded, sagging of the foldable area FA may occur due to a step difference according to a manufacturing process at the lower portion of the supporting member 530. Accordingly, when the crease is deepened, deformation may occur in at least some of the components 510, 520, and 530 of the display device 500. Reliability in operation of the display device 500 may be reduced due to such deformations. In addition, when an upper layer of the display device 500, such as the window 510, is deformed, it may be visually recognized by a user. Accordingly, a structure capable of more strongly supporting the display panel 520 may be desired to prevent the sagging of the foldable area FA.

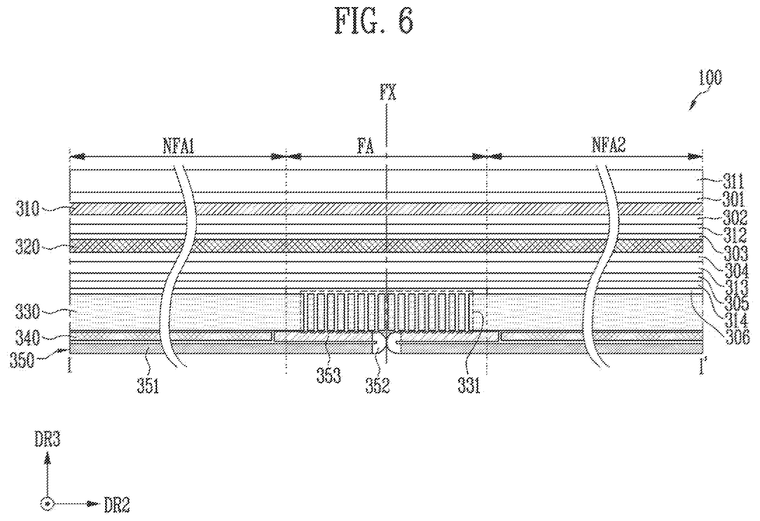

FIG. 6 is a cross-sectional view taken along line I-I′ in the display device of FIG. 1, according to an embodiment of the present invention.

Referring to FIG. 6, the display device 100 may include a window 310, a display panel 320, a first support member 330, an adhesive member 340, and a second support member 350.

The display device 100 may be a structure in which components of a display device 300 are stacked and bonded to each other through adhesive layers 301 to 306. For example, the adhesive layers 301 to 306 may include pressure sensitive adhesives, but are not limited thereto as long as they include materials capable of bonding the components.

A window protection layer 311 of the display device 100 may be disposed at a top of the display device 100 to protect the window 310 that is disposed under the window protection layer 311. The window protection layer 311 may be attached to the window 310 by a first adhesive layer 301. The window protection layer 311 may have a multi-layer structure and may include a restoration layer, a plastic film, and a hard coating layer. For example, as the window protection layer 311 includes the restoration layer, restoration force of the plastic film against external forces such as stamping can be improved. In addition, as the window protection layer 311 includes the hard coating layer, wear resistance of the window protection layer 311 can be increased.

The window 310 may be disposed on the display panel 320 to protect the display panel 320. The window 310 may include an optically transparent insulating material and may have a multi-layer structure or a single-layer structure. For example, the window 310 may include transparent polyimide (colorless polyimide), ultra-thin tempered glass (UTG), polyethylene terephthalate (PET), polyimide (PI), polyethersulfone (PS), polyacrylate (PAR), polyetherimide (PEI), polyethylene naphthalate (PEN), polyphenylene sulfide (PPS), polycarbonate (PC), or the like.

A damping layer 312 may be disposed between the window 310 and the display panel 320. The damping layer 312 may be fixed to the window 310 through a second adhesive layer 302 and may be fixed to the display panel 320 through a third adhesive layer 303. The damping layer 312 may be disposed on the display panel 320 and may absorb external impact to prevent deformation of the display panel 320. For example, the damping layer 312 may prevent the display panel 320 from being deformed by increasing resistance to pressure from a fingernail or impact from a pen or the like. In addition, the damping layer 312 may include a flexible material such as platinum (Pt) and may have a multi-layer structure or a single-layer structure.

As described with reference to FIGS. 1 to 4, the display panel 320 of the display device 100 may display an image and may be folded. The display panel 320 may be divided into the unfoldable areas NFA1 and NFA2 and the foldable area FA disposed between the unfoldable areas NFA1 and NFA2. The display panel 320 may be bent or folded along the folding axis FX in the foldable area FA that is disposed at the center of the display panel 320. Accordingly, appropriate materials and physical properties may be used so that not only the display panel 320 but also the window 310 and the window protection layer 311 disposed on the display panel 320 may be bent or folded along the folding axis FX in the foldable area FA.

A protective film 313 may be disposed under the display panel 320. The protective film 131 may be disposed on a rear surface of the display panel 320 to protect the display panel 320. In addition, the protective film 313 may be coupled to the display panel 320 through a fourth adhesive layer 304. The protective film 313 may prevent scratches on the rear surface of the display panel 320 during a manufacturing process. The protective film 313 may be a colored polyimide film.

In the display panel 320, a cushion member may be disposed under the protective film 313. The cushion member may protect the display panel 320 from an impact transmitted from a lower portion. Impact resistance of the display device 300 can be increased by the cushion member.

In the display panel 320, a barrier layer 314 may be disposed under the protective film 313. The barrier layer 314 may be disposed on the rear surface of the display panel 320 to delay penetration of oxygen and moisture from the outside. In addition, the barrier layer 314 may be coupled to the protective film 313 through a fifth adhesive layer 305. For example, the barrier layer 314 may include of a film having light transmission and double-sided adhesiveness, and may include any one of an olefin-based, acrylic-based, and/or silicon-based insulating material. In addition, the barrier layer 314 may include any one of copolyester thermoplastic elastomer (COP), cycoolefin copolymer (COC), and/or polycarbonate (PC), but the present invention is not limited thereto.

In addition, a sixth adhesive layer 306 may be disposed in the unfoldable areas NFA1 and NFA2 between the barrier layer 314 and the first support member 330 so that the barrier layer 314 and the first support member 330 may be coupled to each other.

The first support member 330 and the second support member 350 of the display device 100 may be disposed under the protective film 313 to support components disposed on the protective film 313. In addition, the first support member 330 and the second support member 350 may prevent the display panel 320 from being twisted due to stress when the display device 100 is in a folded state.

Referring to FIG. 6, the first support member 330 may be provided as one plate integrally formed and may be disposed over the second support member 350. The second support member 350 may be a plurality of sub-plates and may be disposed under the first support member 330. In some embodiments of the present invention, the second support member 350 may include two sub-plates respectively overlapping the first unfoldable area NFA1 and the second unfoldable area NFA2. In addition, the first support member 330 and the second support member 350 may be coupled to each other by the adhesive member 340.

The first support member 330 may be disposed under the display panel 320 to support the display panel 320. In addition, the first support member 330 may include a discontinuous portion 331 having openings or grooves at the center of the display panel 320. For example, the first support member 330 may be one sub-plate disposed to overlap both the unfoldable areas NFA1 and NFA2 and the foldable area FA of the display panel 320. In addition, one sub-plate may include a discontinuous portion 331 overlapping the foldable area FA of the display panel 320. For example, the discontinuous portion 331 might not overlap the unfoldable areas NFA1 and NFA2. For example, the discontinuous portion 331 may be formed adjacent to the folding axis FX. In the discontinuous portion 331, openings penetrating the sub-plate in the third direction DR3 may be formed at regular intervals along the second direction DR2. In addition, in the discontinuous portion 331, grooves penetrating a portion of the sub-plate in the third direction DR3 may be formed at regular intervals along the second direction DR2. The first support member 330 may be easily deformed in the foldable area FA by including the discontinuous portion 331.

The second support member 350 may be disposed under the first support member 330 to support the display panel 320 and the first support member 330. In addition, the second support member 350 may include sub-plates respectively overlapping the foldable areas NFA1 and NFA2, and the sub-plates may be spaced apart from each other in the foldable area FA. For example, the sub-plates of the second support member 350 may be spaced apart from each other in the second direction DR2 in the foldable area FA.

Referring to FIG. 6, each of the sub-plates of the second support member 350 may include a first portion 351, a second portion 352, and a third portion 353. The first portion may extend parallel to the first support member 330. The second portion 352 may extend from the first portion 351 and may be hemmed (or bent) in the foldable area FA, and the third portion 353 may extend parallel to the first support member 330 from the second portion 352.

The second support member 350 may include the first portion 351 disposed at a lowermost portion. The first portion 351 may extend to overlap both the unfoldable areas NFA1 and NFA2 and the foldable area FA. In the first portion 351, each of the sub-plates may extend parallel to the first support member 330 along the second direction DR2 or a direction opposite to the second direction DR2.

The second support member 350 may include the second portion 352 hemmed at an end portion of the first portion 351 overlapping the foldable area FA. In the second portion 352, each of the sub-plates may be bent and hemmed to be fully folded inward. In the second portion 352, each of the sub-plates may be folded inwardly in the third direction DR3 toward the first support member 330 to contact the discontinuous portion 331 of the first support member 330. In the second portion 352, end portions of each of the sub-plates facing each other in the foldable area FA may be rotated and folded. Accordingly, the second support member 350 may have a structure for doubly supporting the discontinuous portion 331 of the first support member 330 by including the second portion 352 and/or the third portion 353 without adding a separate component. Accordingly, stiffness can be increased.

The second support member 350 may include the third portion 353 extending from the second portion 352. The third portion 353 may extend from the second portion 352 and may be disposed parallel to the first support member 330. The third portion 353 may be disposed between the first portion 351 of a corresponding sub-plate and the first support member 330. For example, the third portion 353 may be disposed to overlap a lower portion of the discontinuous portion 331 of the first support member 330 together with a portion of the first portion 351. For example, the portion of the first portion 351 may overlap the lower portion of the discontinuous portion 331. Accordingly, the discontinuous portion 331 of the first support member 330 may be doubly supported by the first portion 351 and the third portion 353 of the second support member 350.

An extended length of the third portion 353 may be determined according to a thickness of the second support member 350. For example, as the thickness of the second support member 350 increases, the length of the third portion 353 extending from the second portion 352 may gradually decrease. For example, when the thickness of the second support member 350 increases, a thickness of the third portion 353 included in the second support member 350 may also increase. Therefore, the third portion 353 may prevent sagging that may be caused in the discontinuous portion 331 even with an area smaller than that of the discontinuous portion 331. Here, the area may be an area in the third direction DR3. For example, as the thickness of the second support member 350 increases, the third portion 353 may be disposed to overlap only a portion of the discontinuous portion 331.

The adhesive member 340 may be disposed between the first support member 330 and the second support member 350. An empty space may be formed between the first support member 330 and the second support member 350 by the second portion 352 in which the second support member 350 is hemmed or bent. In this case, the empty space may be formed at a height equal to the thickness of the second support member 350. In addition, the adhesive member 340 may be disposed to fill the empty space between the first support member 330 and the second support member 350. Accordingly, the adhesive member 340 may be disposed on the first portion 351 of the second support member 350 that does not overlap the third portion 353 extending from the second portion 352 of the second support member 350. For example, the adhesive member 340 may contact the first portion 351 and the third portion 353. In addition, the adhesive member 340 may be disposed to have the same thickness as that of the second support member 350 so that the first portion 351 of the second support member 350 may be attached to the first support member 330. Accordingly, the first support member 330 and the second support member 350 may be coupled to each other without a step difference through the adhesive member 340. For example, the adhesive member 340 may include at least one of a pressure sensitive adhesive, an optically clear adhesive, and/or an optically clear resin. However, the material of the adhesive member 340 is not limited thereto as long as it is a material capable of bonding the first support member 330 and the second support member 350 to each other.

In addition, in the display device 100, an adhesive layer and/or a reinforcing film may be further disposed between the window protection layer 311 and the display panel 320. In addition, in the display device 100, an adhesive layer and/or a reinforcing film may be further disposed between the display panel 320 and the first support member 330.

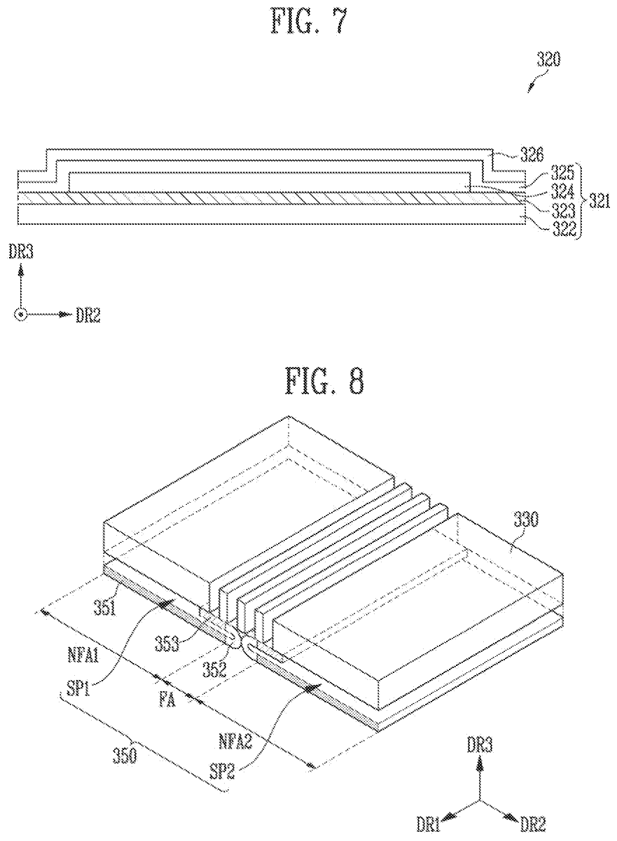

FIG. 7 is a cross-sectional view illustrating of a display panel of FIG. 6, according to an embodiment of the present invention.

The display panel 320 of the display device 100 may generate an image and detect an input received from the outside. Referring to FIG. 7, the display panel 320 may include a display layer 321 and a sensor layer 326.

The display layer 321 may generate an image. The display layer 321 may be a light emitting type display layer. For example, the display layer 321 may be an organic light emitting display layer, a quantum dot display layer, or a micro LED display layer. Depending on a structure of the display layer 321, the display panel 320 may be an organic light emitting display panel, a quantum dot display panel, or a micro LED display panel.

The display layer 321 may include a base layer 322, a circuit layer 323, a light emitting element layer 324, and an encapsulation layer 325.

The base layer 322 may include a substrate. The substrate may include, for example, a glass substrate, an organic/inorganic composite substrate, or the like. For example, the base layer 322 may include a synthetic resin layer. The synthetic resin layer may include a thermosetting resin. The base layer 322 may have a multi-layer structure. For example, the base layer 322 may include a first synthetic resin layer, a silicon oxide (SiOx) layer disposed on the first synthetic resin layer, an amorphous silicon (a-Si) layer disposed on the silicon oxide layer, and a second synthetic layer disposed on the amorphous silicon layer. In some embodiments of the present invention, each of the first and second synthetic resin layers may include at least one of an acrylate-based resin, a methacrylic resin, a polyisoprene-based resin, a vinyl-based resin, an epoxy-based resin, a urethane-based resin, a cellulose-based resin, a siloxane-based resin, a polyamide-based resin, and/or a perylene-based resin.

The circuit layer 323 may be disposed on the base layer 322. The circuit layer 323 may include a plurality of layers for driving the light emitting element layer 324, such as semiconductor patterns, conductive patterns, signal lines, via layers, and insulating layers. For example, the semiconductor patterns and the conductive patterns may include pixel circuits for driving light emitting elements of the light emitting element layer 324. The pixel circuits may be controlled through the signal lines.

The light emitting element layer 324 may be disposed on the circuit layer 323. The light emitting element layer 324 may include light emitting elements. For example, the light emitting element layer 324 may include organic light emitting materials, quantum dots, quantum rods, or micro LEDs.

The encapsulation layer 325 may be disposed on the light emitting element layer 324 to protect components of the display layer 321, such as the light emitting element layer 324, from the external environment. The encapsulation layer 325 may include inorganic layers and at least one organic layer stacked on each other. For example, the encapsulation layer 325 may include an inorganic layer, an organic layer, and an inorganic layer sequentially stacked on each other. The inorganic layers may protect the light emitting element layer 324 from moisture and oxygen, and the organic layer may protect the light emitting element layer 324 from foreign substances such as dust particles.

The sensor layer 326 may be disposed on the display layer 321. The sensor layer 326 may detect an external input received from the outside. The external input may be a user's input. The user's input may include at least one external input among various forms such as a part of the user's body, light, heat, an object (e.g., a pen), and pressure.

In some embodiments of the present inventive concept, the sensor layer 326 may be directly disposed on the display layer 321. For example, a separate adhesive member is not disposed between the sensor layer 326 and the display layer 321, and the sensor layer 326 may use a component of the display layer 321 such as the encapsulation layer 325 as a substrate. Further, as an example, sensor units of the sensor layer 326 may be formed on the encapsulation layer 325. In addition, the sensor layer 326 may be formed separately from the display layer 321 and then coupled to the display layer 321 through an adhesive member. The adhesive layer may include an adhesive and/or a pressure-sensitive adhesive.

FIG. 8 is a perspective view illustrating a first support member and a second support member of FIG. 6, according to an embodiment of the present invention. The display device 100 may include the first support member 330 and a second support member 350. The first support member 330 may include one sub-plate and may be disposed under the display panel 320, and the second support member 350 may include a plurality of sub-plates and may be disposed under the first support member 330.

Referring to FIGS. 6 and 8, the first support member 330 may include one sub-plate continuously extending in the first unfoldable area NFA1, the foldable area FA, and the second unfoldable area NFA2. In addition, the first support member 330 may include the discontinuous portion having openings or grooves in the foldable area FA so that the one sub-plate can be easily folded.

The first support member 330 may include a material having a relatively high rigidity to be suitable for supporting components (e.g., the display panel 320) that are disposed thereon. In some embodiments of the present invention, the first support member 330 may include at least one of stainless steel, aluminum alloy, copper alloy, plastic (Carbon Fiber Reinforced Plastics), and/or ultra thin glass. However, the material of the first support member 330 is not limited thereto as long as it is suitable for supporting the components disposed thereon.

Referring to FIGS. 6 and 8, the display device 100 is in an unfolded state, and the second support member 350 may include a first sub-plate SP1 and a second sub-plate SP2. The first sub-plate SP1 may be disposed to correspond to (e.g., overlap) the first unfoldable area NFA1 and the foldable area FA, and the second sub-plate SP2 may be disposed to correspond to the second unfoldable area NFA2 and the foldable area FA. In addition, the second support member 350 may overlap the first support member 330 and may be attached to the first support member 330 by the adhesive member 340.

The second support member 350 may include a material having a relatively high rigidity to be suitable for supporting components (e.g., the display panel 320 and the first support member 330) disposed thereon. In some embodiments of the present invention, the second support member 350 may include at least one of stainless steel, aluminum alloy, and copper alloy. However, the material of the second support member 350 is not limited thereto as long as the material is suitable for supporting the components disposed thereon.

According to an embodiment of the present invention, each of the first sub-plate SP1 and the second sub-plate SP2 may include the first portion 351, the second portion 352, and the third portion 353. The first portion 351 may extend parallel to the first supporting member 330, and the second portion 352 may extend from the first portion 351 and may be hemmed in the foldable area FA. The third portion 353 may extend parallel to the first support member 330 from the second portion 352.

Each of a portion of the first sub-plate SP1 and a portion of the second sub-plate SP2 may overlap the foldable area FA. The first sub-plate SP1 and the second sub-plate SP2 may be disposed to be spaced apart from each other in the foldable area FA, but the width of the space between the first sub-plate SP1 and the second sub-plate SP2 may be smaller than that of the foldable area FA. In addition, even though the figures might not illustrate a noticeable space between the first sub-plate SP1 and the second sub-plate SP2, the space between the first sub-plate SP1 and the second sub-plate SP2 may be very small. For example, the ends of the first sub-plate SP1 and the second sub-plate SP2 facing each other in the foldable area FA may be hemmed. For example, the first sub-plate SP1 is not connected to the second sub-plate SP2 through their second portions 352. Accordingly, the discontinuous portion, in which the openings or grooves of the first support member 330 are disposed, may be overlapped and supported by the hemmed ends of the first sub-plate SP1 and the second sub-plate SP2. For example, each of the first sub-plate SP1 and the second sub-plate SP2 may include the second portion 352 that is hemmed at an end portion, of the corresponding sub-plate SP1 or SP2, adjacent to the folding axis FX. The second portion 352 may be curved with a predetermined curvature. In addition, the first portion 351 and the third portion 353 of the first sub-plate SP1 may be stacked and arranged in two stages by the second portion 352. In addition, the first portion 351 and the third portion 353 of the second sub-plate SP2 may be stacked and arranged in two stages by the second portion 352. For example, under the discontinuous portion of the foldable area FA, the third portion 353 and the first portion 351 of each of the sub-plates SP1 and SP2 may be disposed to overlap each other or the second portion 352 may be disposed in a direction substantially perpendicular to the first support member 330.

The first sub-plate SP1 and the second sub-plate SP2 may overlap the first unfoldable area NFA1 and the second unfoldable area NFA2, respectively. In addition, each of the first sub-plate SP1 and the second sub-plate SP2 may be attached to the first support member 330 by the adhesive member 340. For example, the first portion 351 of the first sub-plate SP1 may be disposed to overlap the first unfoldable area NFA1. In addition, the adhesive member 340 may couple the first portion 351 of the first sub-plate SP1 to the first support member 330 in the first unfoldable area NFA1 and may couple the first portion 351 of the second sub-plate SP2 to the first support member 330 in the second unfoldable area NFA2. Here, the adhesive member 340 may be disposed on a portion of the first portion 351 that does not overlap the third portion 353 of the first sub-plate SP1 in the first foldable area NFA1. In addition, the adhesive member 340 may be disposed on a portion of the first portion 351 that does not overlap the third portion 353 of the second sub-plate SP2 in the second unfoldable area NFA2. For example, in the first unfoldable area NFA1 and the second unfoldable area NFA2, the first portion 351 of each of the sub-plates SP1 and SP2 may be disposed to be attached under the first support member 330 by the adhesive member 340.

In this way, by forming the second portion 352 in which a portion of the second support member 350 is hemmed, the second support member 350 may support the discontinuous portion 351 of the first support member 330 from below without a step difference. Accordingly, the amount of sagging of the first support member 330 and components disposed above the first support member 330 may be reduced. In addition, when the display device 100 is repeatedly folded, stress applied to the first support member 330 and the components disposed above the first support member 330 in the foldable area FA may be reduced, thereby providing the display device 100 with increased durability.

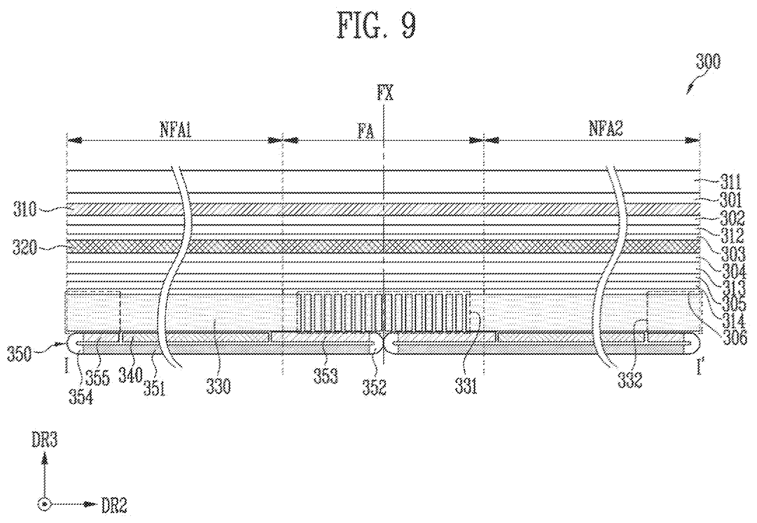

FIG. 9 is a cross-sectional view taken along line I-I′ in the display device of FIG. 1, according to an embodiment of the present invention.

Referring to FIG. 9, the display device 100 may include a window 310, a display panel 320, a first support member 330, an adhesive member 340, and a second support member 350. A window protection layer 311, a window 310, and the like may be disposed on an upper portion (e.g., an upper surface) of the display panel 320, and a protective film 313, a barrier layer 314, the first support member 330, the adhesive member 340, the second support member 350, and the like may be disposed on a lower portion (e.g., a lower surface) of the display panel 320. In addition, the display panel 320 may have the same configuration as that of FIG. 7 except for the inclusion of the fourth portion 354 and the fifth portion 355. Hereinafter, duplicate descriptions will be omitted or briefly discussed and differences will be mainly discussed.

The second support member 350 may be disposed under the first support member 330 to support the display panel 320 and the first support member 330. In addition, the second support member 350 may include sub-plates respectively overlapping the first and second unfoldable areas NFA1 and NFA2. The sub-plates may be spaced apart from each other in the foldable area FA. For example, the sub-plates of the second support member 350 may be disposed to overlap each of the unfoldable areas NFA1 and NFA2, and to be spaced apart from each other in the second direction DR2 in the foldable area FA.

Referring to FIG. 9, each of the sub-plates of the second support member 350 may include a first portion 351, a second portion 352, and a third portion 353. The first portion 351 may extend parallel to the first support member 330, and the second portion 352 may extend from the first portion 351 and may be hemmed in the foldable area FA. The third portion 353 may extend parallel to the first support member 330 from the second portion 352. In addition, each of the sub-plates of the second support member 350 may further include a fourth portion 354 and a fifth portion 355. The fourth portion 354 may extend from the first portion 351 and may be hemmed, and the fifth portion 355 may extend parallel to the first support member 330 from the fourth portion 354. The first portion 351 may be disposed between the second portion 352 and the fourth portion 354 where each of the sub-plates are hemmed.

The second support member 350 may include the first portion 351 disposed at a lowermost portion of the display device 300. The first portion 351 may extend to overlap both the first and second unfoldable areas NFA1 and NFA2 and the foldable area FA. In the first portion 351, each of the sub-plates may extend parallel to the first support member 330 along the second direction DR2 or a direction opposite to the second direction DR2.

The second support member 350 may include the fourth portion 354 hemmed at an end portion of the first portion 351 overlapping edge portions of the first and second unfoldable areas NFA1 and NFA2. Like the second portion 352, the fourth portion 354 may be bent and hemmed so that each of the sub-plates is fully folded inwardly. The fourth portion 354 may contact an edge portion 332 of the first support member 330 by being folded inwardly in the third direction DR3 so that each of the sub-plates faces the first support member 330. The fourth portion 354 may be folded by curving an end portion of each of the sub-plates spaced apart from the folding axis FX in the second direction DR2. Accordingly, like the second portion 352, the second support member 350 may have a configuration in which the edge portion 332 of the first support member 330 is doubly supported by the fourth portion 354 without adding a separate component, so that stiffness can be increased.

The second support member 350 may include the fifth portion 355 extending from the fourth portion 354. The fifth portion 355 may extend from the fourth portion 354 and may be disposed parallel to the first support member 330. The fifth portion 355 may be disposed between the first portion 351 of each of the sub-plates corresponding to the second support member 350 and the first support member 330. For example, the fifth portion 355 may be disposed to overlap a lower portion of the edge portion332 and/or a portion adjacent to the edge portion 332 of the first support member 330 together with a portion of the first portion 351. Accordingly, the edge portion 332 and/or the portion adjacent to the edge portion 332 of the first support member 330 may be doubly supported by the first portion 351 and the fifth portion 355 of the second support member 350.

An extended length of the fifth portion 355 may be determined according to the thickness of the second support member 350. For example, as the thickness of the second support member 350 increases, the length of the fifth portion 355 extending from the fourth portion 354 may gradually decrease. For example, when the thickness of the second support member 350 increases, the thickness of the fifth portion 355 included in the second support member 350 may also increases, so that the fifth portion 355 may prevent sagging caused in the edge portion 332 even with an area smaller than that of the edge portion 332. Here, for example, the area may be an area in the third direction DR3. For example, as the thickness of the second support member 350 increases, the fifth portion 355 may be disposed to overlap only a portion of the edge portion 332.

The adhesive member 340 may be disposed between the first support member 330 and the second support member 350. An empty space may be formed between the first support member 330 and the second support member 350 by the second portion 352 and the fourth portion 354 in which the second support member 350 is hemmed. In this case, the empty space may be formed at a height equal to the thickness of the second support member 350. For example, the empty space may be formed between the first portion 351, the fifth portion 355, the third portion 353 and the first support member 330. In addition, the adhesive member 340 may be disposed to fill the empty space between the first support member 330 and the second support member 350. Accordingly, the adhesive member 340 may be disposed on the first portion 351 of the second support member 350 and disposed between the third portion 353 and the fifth portion 355. In addition, the adhesive member 340 may be disposed to have the same thickness as the second support member 350 so that the first portion 351 of the second support member 350 may be attached to the first support member 330. Accordingly, the first support member 330 and the second support member 350 may be coupled to each other without a step difference through the adhesive member 340. For example, the adhesive member 340 may include at least one of a pressure sensitive adhesive, an optically clear adhesive, and/or an optically clear resin. However, the material of the adhesive member 340 is not limited thereto as long as it is a material capable of bonding the first support member 330 and the second support member 350 to each other.

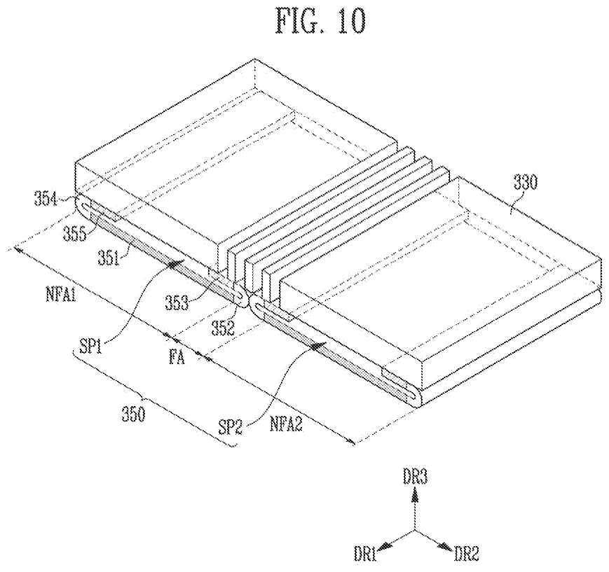

FIG. 10 is a perspective view illustrating a first support member and a second support member of FIG. 9, according to an embodiment of the present invention. The first support member 330 may have the same configuration as that of FIG. 8. Hereinafter, duplicate descriptions will be omitted or briefly discussed, and differences will be mainly discussed.

Referring to FIGS. 9 and 10, when the display device 100 is in an unfolded state, the second support member 350 may include the first sub-plate SP1 and the second sub-plate SP2. The first sub-plate SP1 may be disposed to correspond to the first unfoldable area NFA1 and the foldable area FA, and the second sub-plate SP2 may be disposed to correspond to the second unfoldable area NFA2 and the foldable area FA. In addition, the second support member 350 may overlap the first support member 330 and may be attached to the first support member 330 by the adhesive member 340.

According to an embodiment of the present invention, each of the first sub-plate SP1 and the second sub-plate SP2 may include a first portion 351, a second portion 352, and a third portion 353. The first portion 351 may extend parallel to the first support member 330, and the second portion 352 may extend from the first portion 351 and may be hemmed in the foldable area FA. The third portion 353 may extend parallel to the first support member 330 from the second portion 352. In addition, each of the first sub-plate SP1 and the second sub-plate SP2 may include a fourth portion 354 and a fifth portion 355. The fourth portion 354 may extend from the first portion 351 and may be hemmed in the foldable area FA, and the fifth portion 355 may extend parallel to the first support member 330 from the fourth portion 354.

Each of a portion of the first sub-plate SP1 and a portion of the second sub-plate SP2 may overlap an edge portion 332 of the first support member 330. For example, end portions of the first sub-plate SP1 and the second sub-plate SP2 overlapping the edge portion 332 of the first supporting member 330 may be hemmed to support the edge portion 332. For example, each of the first sub-plate SP1 and the second sub-plate SP2 may include the fourth portion 354 hemmed at an end portion spaced apart from the folding axis FX in the second direction DR2 or in a direction opposite to the second direction DR2. The fourth portion 354 may be curved with a predetermined curvature. In addition, the first portion 351 and the fifth portion 355 of the first sub-plate SP1 may be stacked by the fourth portion 354 and arranged in two stages, and the first portion 351 and the fifth portion 355 of the second sub-plate SP2 may be stacked by the fourth portion 354 and arranged in two stages. For example, in the first and second unfoldable areas NFA1 and NFA2, the fifth portion 355 and the first portion 351 of each of the sub-plates SP1 and SP2 may be stacked in two stages under the edge portion 332, or the fourth portion 354 may be disposed in a direction substantially perpendicular to the first support member 330.

Each of the first sub-plate SP1 and the second sub-plate SP2 may overlap the first unfoldable area NFA1 and the second unfoldable area NFA2, respectively. In addition, each of the first sub-plate SP1 and the second sub-plate SP2 may be attached to the first support member 330 by the adhesive member 340. For example, the first portion 351 of the first sub-plate SP1 may be disposed to overlap the first unfoldable area NFA1. In addition, the adhesive member 340 may couple the first portion 351 of the first sub-plate SP1 to the first support member 330 in the first unfoldable area NFA1, and may couple the first portion 351 of the second sub-plate SP2 to the first support member 330 in the second unfoldable area NFA2. Here, the adhesive member 340 may be disposed on a portion of the first portion 351 that does not overlap the third portion 353 and the fifth portion 355 of the first sub-plate SP1 in the first foldable area NFA1. In addition, the adhesive member 340 may be disposed on a portion of the first portion 351 that does not overlap the third portion 353 and the fifth portion 355 of the second sub-plate SP2 in the second unfoldable area NFA2. For example, in the first unfoldable area NFA1 and the second unfoldable area NFA2, the first portion 351 of each of the sub-plates SP1 and SP2 may be disposed to be attached to the lower portion of the first support member 330 by the adhesive member 340.

In this way, by forming the second portion 352 and the fourth portion 354 in which portions of the second support member 350 are hemmed, the second support member 350 may support the lower portion of the first support member 330 without a step difference formed by the adhesive member 340 and the second support member 350 according to the thickness of the adhesive member 340. Accordingly, the amount of sagging of the first support member 330 and components disposed above the first support member 330 may be reduced. For example, as the fourth portion 354 of the second support member 350 is formed, an edge portion of the display panel 320 can be protected, thereby providing the display device 100 with increased durability.

According to embodiments of the present invention, a display device having increased reliability may be provided.

Effects according to embodiments of the present invention are not limited by the above-described contents, and various other effects are included in the present specification.

While the present invention has been particularly shown and described with reference to embodiments thereof, it will be apparent those of ordinary skill in the art that various changes in form and detail may be made thereto without departing from spirit and scope of the present invention.

What is claimed is:

1. A display device comprising:
unfoldable areas and foldable areas disposed between the unfoldable areas;
a window;
a display panel disposed under the window;
a first support member disposed under the display panel in the unfoldable areas and the foldable area to support the display panel, and including a discontinuous portion having openings or grooves in the foldable area;
a second support member disposed under the first support member and including sub-plates respectively overlapping the unfoldable areas; and
an adhesive member disposed between the first support member and the second support member,
wherein each of the sub-plates of the second support member includes a first portion, a second portion, and a third portion, wherein the first portion extends parallel to the first support member, wherein the second portion extends from the first portion and is bent in the foldable area, and wherein the third portion extends parallel to the first support member from the second portion.

2. The display device of claim 1, wherein the second portion of each of the sub-plates is folded inwardly in a direction toward the first support member to contact the discontinuous portion of the first support member.

3. The display device of claim 1, wherein the sub-plates are spaced apart from each other in the foldable area.

4. The display device of claim 3, wherein the second portion of each of the sub-plates is folded by bending end portions of the sub-plates facing each other in the foldable area.

5. The display device of claim 1, wherein the third portion of each of the sub-plates is disposed between the first portion of a corresponding sub-plate and the first support member.

6. The display device of claim 1, wherein the adhesive member is disposed on a portion of the first portion that does not overlap the third portion of each of the sub-plates.

7. The display device of claim 6, wherein the adhesive member is disposed to have the same thickness as the second support member, wherein the adhesive member attaches the first portion to the first support member.

8. The display device of claim 1, wherein the adhesive member includes at least one of a pressure sensitive adhesive, an optically clear adhesive, or an optically clear resin.

9. The display device of claim 1, wherein the first support member includes at least one of stainless steel, aluminum alloy, copper alloy, plastic (carbon fiber reinforced plastics), or ultra thin glass.

10. The display device of claim 1, wherein the second support member includes at least one of stainless steel, aluminum alloy, or copper alloy.

11. The display device of claim 1, wherein each of the sub-plates of the second support member further includes a fourth portion and a fifth portion, wherein the fourth portion extends from the first portion and is bent, and wherein the fifth portion extends parallel to the first support member from the fourth portion, and
wherein the first portion is disposed between the second portion and the fourth portion.

12. The display device of claim 11, wherein the fourth portion of each of the sub-plates is folded inwardly in a direction toward the first support member to contact an edge portion of the first support member.

13. The display device of claim 11, wherein the fifth portion of each of the sub-plates is disposed between the first portion of a corresponding sub-plate and the first support member.

14. The display device of claim 13, wherein the adhesive member is disposed on the first portion of each of the sub-plates and is disposed between the third portion and the fifth portion.

15. A display device comprising:
unfoldable areas and foldable areas disposed between the unfoldable areas;
a window;
a display panel disposed attached to the window;
a first support member attached to the display panel in the unfoldable areas and the foldable area, and including a discontinuous portion having openings or grooves in the foldable area;
a second support member disposed under the first support member and including sub-plates respectively overlapping the unfoldable areas and the foldable area; and
wherein each of the sub-plates of the second support member includes a first portion, a second portion, and a third portion, wherein the first portion overlaps the first support member, wherein the second portion extends from the first portion and is bent in the foldable area, and wherein the third portion is disposed between the first support member and the first portion.

16. The display device of claim 15, further comprising an adhesive member disposed between the first portion and the first support member.

17. The display device of claim 16, wherein the adhesive member contacts the first portion and the third portion.

18. The display device of claim 15, wherein each of the sub-plates of the second support member further includes a fourth portion and a fifth portion, wherein the fourth portion is connected to the first portion and is bent, and wherein the fifth portion is connected to the fourth portion, and
wherein the first portion is disposed between the second portion and the fourth portion.

19. The display device of claim 18, the fifth portion is disposed between the first portion and the first support member.

20. The display device of claim 18, further comprising an adhesive member disposed between the fifth portion and the third portion.
